(19) United States
(12) Patent Application Publication
(10) Pub. No.: US 2023/0186001 A1
(43) Pub. Date: Jun. 15, 2023

(54) METHOD AND SYSTEM FOR SIMULATING AN EVENT

(71) Applicant: HIFI ENGINEERING INC., Calgary (CA)

(72) Inventors: Seyed Ehsan JALILIAN, Calgary (CA); Sahil DHANKHAD, Calgary (CA); Shayan ZAMANI, Calgary (CA); Arne DANKERS, Calgary (CA); Mehri OWJIMEHR, Calgary (CA); Yuhong LIU, Calgary (CA)

(21) Appl. No.: 18/065,486

(22) Filed: Dec. 13, 2022

Related U.S. Application Data
(60) Provisional application No. 63/288,763, filed on Dec. 13, 2021.

(51) Int. Cl. G06F 30/27; G01M 3/24; G01D 5/353; G06N 3/045

(52) U.S. Cl. CPC G06F 30/27; G01M 3/243; G01D 5/35316; G06N 3/045

(57) ABSTRACT

Methods, systems, and techniques for simulating an event. Simulated event data comprising a simulated event, and authentic raw data, are both obtained. The simulated event data and the authentic raw data are blended to form blended data that comprises the simulated event. The blended data may be fed into an event detection system, such as a pipeline leak detection system, for testing purposes.

### CROSS REFERENCE TO RELATED APPLICATIONS

This application is related to and claims priority to U.S. Provisional Patent Application No. 63/288,763 filed on Dec. 13, 2021, the contents of which are incorporated by reference herein.

### TECHNICAL FIELD

The present disclosure is directed at methods, systems, and techniques for simulating an event.

### BACKGROUND

The combination of ubiquitous Internet connectivity, the prevalence of various types of electronic sensors, and the dropping cost of data storage has resulted in seemingly ever increasing amounts of data being collected and stored. This data is often analyzed to determine whether it contains certain “events” as measured by the sensors, the nature of which are context-dependent. Given the amount of data that is collected and consequently needs to be analyzed, that analysis is often done using computer-implemented methods, such as by applying machine learning.

### SUMMARY

According to a first aspect, there is provided a method comprising obtaining simulated event data comprising a simulated event and authentic raw data; and combining the simulated event data and the authentic raw data to form blended data that comprises the simulated event.

The method may further comprise subsequently processing the blended data and identifying the simulated event therein.

Combining the simulated event data and the raw data to form blended data may comprise: respectively converting the simulated event data and the authentic raw data into frequency domain representations thereof; summing the frequency domain representations of the simulated event data and the authentic raw data together to form a frequency domain representation of the blended data; and converting the frequency domain representation of the blended data into a time domain representation of the blended data.

The blended data may be expressed as a power spectral density.

The simulated event data may be expressed as a power spectral density when combined with the authentic raw data.

The simulated event data may comprise recorded authentic events.

The method may further comprise generating the simulated event data using a generative adversarial network, and some of the authentic raw data may be input to the generative adversarial network to permit generation of the simulated event data.

The generative adversarial network may comprise a generator and a discriminator, all layers except an output layer of the discriminator may use leaky rectified linear unit activation, the output layer of the discriminator may use tan h activation, and all layers of the generator may use leaky rectified linear unit activation.

The authentic raw data may comprise acoustic data.

Obtaining the authentic raw data may comprise performing optical fiber interferometry using fiber Bragg gratings.

Obtaining the authentic raw data may comprise performing distributed acoustic sensing.

The authentic raw data may be obtained and combined with the simulated event data in real-time.

The authentic raw data may be obtained by recording acoustics proximate a pipeline, and the simulated event may comprise a pipeline leak.

According to another aspect, there is provided a system comprising: a processor; a database that is communicatively coupled to the processor and that has simulated event data stored thereon; a memory that is communicatively coupled to the processor and that has stored thereon computer program code that is executable by the processor and that, when executed by the processor, causes the processor to perform the foregoing method.

According to another aspect, there is provided a non-transitory computer readable medium having stored thereon computer program code that is executable by a processor and that, when executed by the processor, causes the processor to perform the foregoing method.

This summary does not necessarily describe the entire scope of all aspects. Other aspects, features and advantages will be apparent to those of ordinary skill in the art upon review of the following description of specific embodiments.

### BRIEF DESCRIPTION OF THE DRAWINGS

In the accompanying drawings, which illustrate one or more example embodiments:

FIG. 1A is a block diagram of a system for determining whether an event has occurred from dynamic strain measurements, which includes an optical fiber with fiber Bragg gratings (“FBGs”) for reflecting a light pulse, in accordance with an example embodiment.

FIG. 1B is a schematic diagram that depicts how the FBGs reflect a light pulse, in accordance with an example embodiment.

FIG. 1C is a schematic diagram that depicts how a light pulse interacts with impurities in an optical fiber that results in scattered laser light due to Rayleigh scattering, which is used for distributed acoustic sensing (“DAS”), in accordance with an example embodiment.

FIG. 2A depicts an event detection system operating in accordance with the prior art.

FIG. 2B depicts an event detection system operating in accordance with an example embodiment.

FIG. 3 depicts a method for simulating an event, according to an example embodiment.

FIGS. 4 and 5 depict systems for simulating an event, according to example embodiments.

FIG. 6 depicts a generative adversarial network for generating simulated events, according to an example embodiment.

FIG. 7 depicts a generator and discriminator that comprise part of the generative adversarial network of FIG. 6, according to an example embodiment.

FIG. 8 depicts a block diagram depicting the layers of an example generator comprising part of the generative adversarial network of FIG. 6, according to an example embodiment.

FIG. 9 depicts a block diagram depicting the layers of an example discriminator comprising part of the generative adversarial network of FIG. 6, according to an example embodiment.

FIGS. 10A and 10B respectively depict power spectral densities of authentic leaks and simulated leaks used to train a deep convolutional generative adversarial network and generated by the trained deep convolutional generative adversarial network, according to an example embodiment.

FIG. 11 depicts how a generative adversarial network generates better power spectral densities of a simulated leak with additional training, according to an example embodiment.

FIG. 12 depicts an example computer system that may be used to generate a simulated event, according to an example embodiment.

### DETAILED DESCRIPTION

A variety of types of data can be electronically collected using sensors for processing, which processing may be performed in real-time and/or in a delayed fashion if the collected data is stored for subsequent processing. This data may be processed by a computer system in order to detect “events” in that data, with the nature of the event depending at least in part on the type of data being processed.

For example, the data may be collected using sensors that comprise part of:

1. a pipeline leak detection system, and the event may comprise a leak in the pipeline;
2. a perimeter security system, and the event may comprise an intrusion event;
3. a patient monitoring system, and the event may comprise a cardiac event;
4. a geotechnical monitoring system, and the event may comprise a strain event; or
5. a camera-based event detection system, and the event may comprise any sort of anomalous visual event captured by the camera, such as the presence of a particular gas in the environment.

A machine learning based system, such as an object classifier used to classify images captured from a camera that is implemented using an artificial neural network, such as a convolutional neural network, may be used for computer-implemented event detection.

An event that is represented in data recorded by the sensors is herein referred to as an “authentic event”. Depending on the nature of the system, authentic events may be very rare. In fact, for some systems such as a pipeline leak detection system, authentic events may ideally never occur. Regardless, it is important to periodically test the event detection system, particularly when authentic events are infrequent but serious.

Testing may in some situations be done by physically creating an authentic event and then monitoring the event detection system's response to it. However, this can be costly and risky, such as in the context of a pipeline leak. Moreover, in some situations it may not be possible: sensors may be inaccessible (e.g., they may be buried), or an authentic event may simply not be able to be created (e.g., for a patient monitoring system, it is not feasible to test using an authentic, acute medical event).

Consequently, in at least some embodiments herein, a “simulated event” may at least in part be computer generated and input to the event detection system. The simulated event is designed to mimic an authentic event. The response of the event detection system to one or more simulated events may be monitored, and the event detection system may consequently be tested in this manner. The simulated event may be generated using, for example, an artificial neural network such as a generative adversarial network (“GAN”). Additionally or alternatively, the simulated event may be generated based off a recording of an authentic event and blended with a data stream for processing by the event detection system. The integration of the simulated event with the data stream is performed in a manner that prevents the event detection system from recognizing the simulated event by virtue of how it is integrated into the data stream.

By using simulated events in this manner, the need to go into the field and replicate authentic events for testing is eliminated. Further, simulated events can be introduced into the event detection system's data stream under any number of ambient conditions, which may be difficult to replicate in the field. Simulated events may also be easily triggered as desired: they may, for example, be used on demand; periodically according to a preset schedule, or upon detection or determination of a certain condition (e.g., when measured noise levels go high, a simulated event may be introduced to see if the event is still detectable despite the event detection system having to perform processing with a higher noise floor).

As mentioned above, in at least some example embodiments the event detection system comprises a pipeline leak detection system. In those embodiments, leaks may be detected as acoustic events. Fiber optic cables are often used as distributed measurement systems in acoustic sensing applications. Pressure changes, due to sound waves for example, in the space immediately surrounding an optical fiber and that encounter the optical fiber cause dynamic strain in the optical fiber. Optical interferometry may be used to detect the dynamic strain along a segment of the fiber. Optical interferometry is a technique in which two separate light pulses, a sensing pulse and a reference pulse, are generated and interfere with each other. The sensing and reference pulses may, for example, be directed along an optical fiber that comprises fiber Bragg gratings. The fiber Bragg gratings partially reflect the pulses back towards an optical receiver at which an interference pattern is observed.

The nature of the interference pattern observed at the optical receiver provides information on the optical path length the pulses traveled, which in turn provides information on parameters such as the strain experienced by the segment of optical fiber between the fiber Bragg gratings. Information on the strain then provides information about the event that caused the strain.

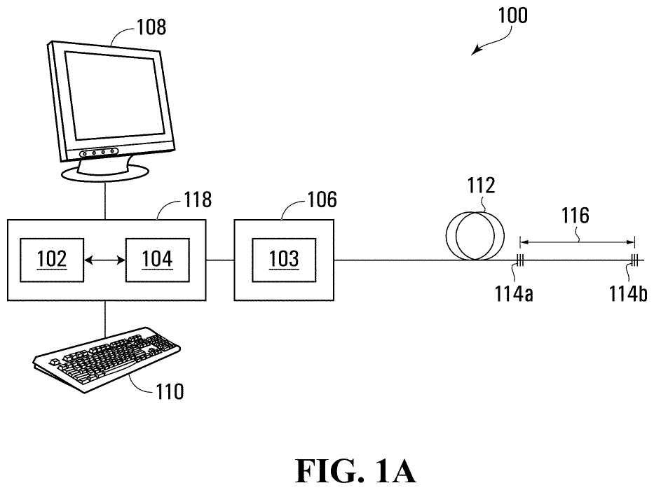

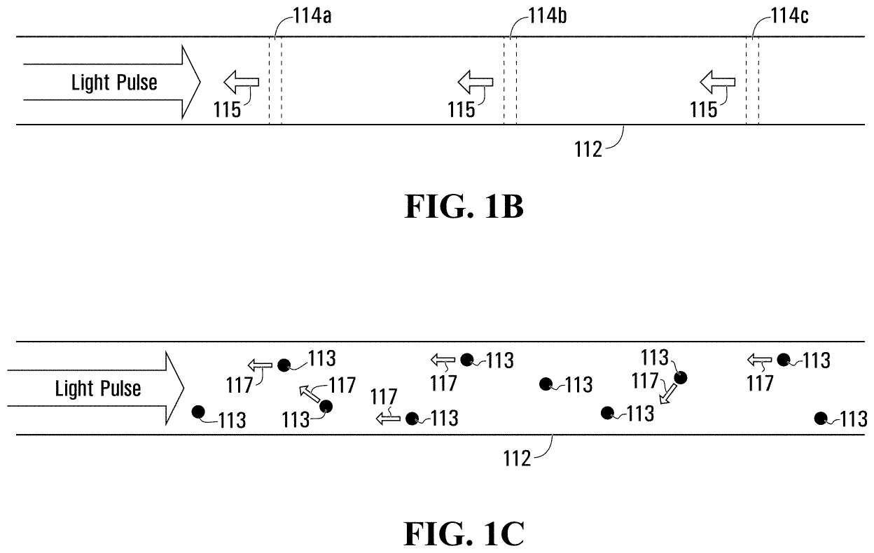

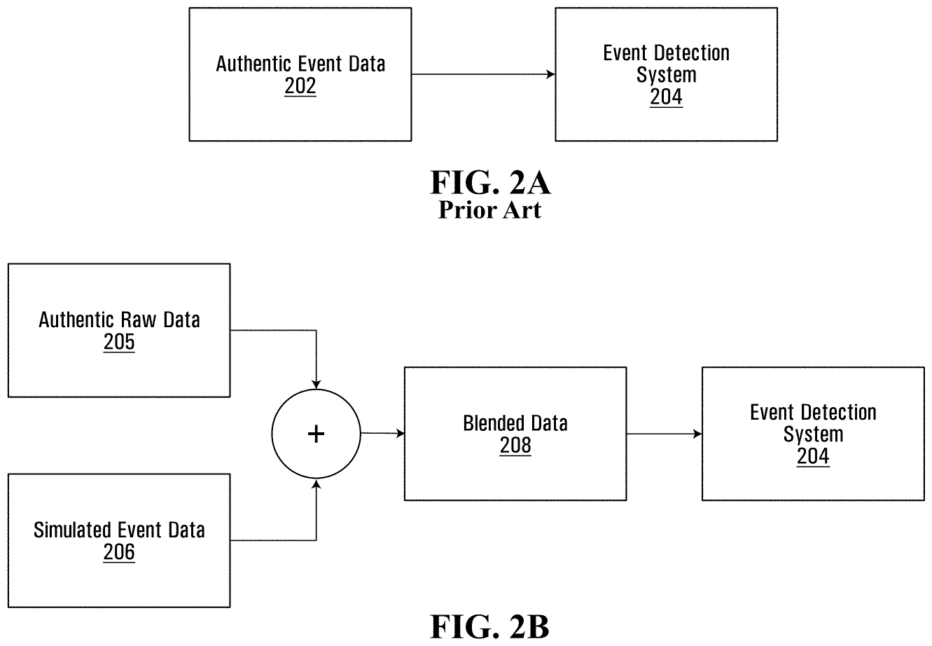

Referring now to FIG. 1A, there is shown one embodiment of a system 100 for performing interferometry using fiber Bragg gratings (“FBGs”), in accordance with embodiments of the disclosure. The system 100 comprises optical fiber 112, an interrogator 106 optically coupled to the optical fiber 112, and a signal processing device 118 that is communicative with the interrogator 106.

The optical fiber 112 comprises one or more fiber optic strands, each of which is made from quartz glass (amorphous SiO₂). The fiber optic strands are doped with various elements and compounds (including germanium, erbium oxides, and others) to alter their refractive indices, although in alternative embodiments the fiber optic strands may not be doped. Single mode and multimode optical strands of fiber are commercially available from, for example, Corning® Optical Fiber. Example optical fibers include ClearCurve™ fibers (bend insensitive), SMF28 series single mode fibers such as SMF-28 ULL fibers or SMF-28e fibers, and InfiniCor® series multimode fibers.

The interrogator 106 generates the sensing and reference pulses and outputs the reference pulse after the sensing pulse. The pulses are transmitted along optical fiber 112 that comprises a first pair of FBGs. The first pair of FBGs comprises first and second FBGs 114a,b (generally, “FBGs 114”). The first and second FBGs 114a,b are separated by a certain segment 116 of the optical fiber 112 (“fiber segment 116”). The optical length of the fiber segment 116 varies in response to dynamic strain that the fiber segment 116 experiences.

The light pulses have a wavelength identical or very close to the center wavelength of the FBGs 114, which is the wavelength of light the FBGs 114 are designed to partially reflect; for example, typical FBGs 114 are tuned to reflect light in the 1,000 to 2,000 nm wavelength range. The sensing and reference pulses are accordingly each partially reflected by the FBGs 114a,b and return to the interrogator 106. The delay between transmission of the sensing and reference pulses is such that the reference pulse that reflects off the first FBG 114a (hereinafter the “reflected reference pulse”) arrives at the optical receiver 103 simultaneously with the sensing pulse that reflects off the second FBG 114b (hereinafter the “reflected sensing pulse”), which permits optical interference to occur.

While FIG. 1A shows only the one pair of FBGs 114a,b, in alternative embodiments (not depicted) any number of FBGs 114 may be on the fiber 112, and time division multiplexing (TDM) (and, optionally, wavelength division multiplexing (WDM)) may be used to simultaneously obtain measurements from them. If two or more pairs of FBGs 114 are used, any one of the pairs may be tuned to reflect a different center wavelength than any other of the pairs. Alternatively, a group of multiple FBGs 114 may be tuned to reflect a different center wavelength to another group of multiple FBGs 114, and there may be any number of groups of multiple FBGs extending along the optical fiber 112 with each group of FBGs 114 tuned to reflect a different center wavelength. In these example embodiments where different pairs or group of FBGs 114 are tuned to reflect different center wavelengths to other pairs or groups of FBGs 114, WDM may be used in order to transmit and to receive light from the different pairs or groups of FBGs 114, effectively extending the number of FBG pairs or groups that can be used in series along the optical fiber 112 by reducing the effect of optical loss that otherwise would have resulted from light reflecting from the FBGs 114 located on the fiber 112 nearer to the interrogator 106. When different pairs of the FBGs 114 are not tuned to different center wavelengths, TDM is sufficient.

The interrogator 106 emits laser light with a wavelength selected to be identical or sufficiently near the center wavelength of the FBGs 114, and each of the FBGs 114 partially reflects the light back towards the interrogator 106. The timing of the successively transmitted light pulses is such that the light pulses reflected by the first and second FBGs 114a,b interfere with each other at the interrogator 106, which records the resulting interference signal. The strain that the fiber segment 116 experiences alters the optical path length between the two FBGs 114 and thus causes a phase difference to arise between the two interfering pulses. The resultant optical power at the optical receiver 103 can be used to determine this phase difference. Consequently, the interference signal that the interrogator 106 receives varies with the strain the fiber segment 116 is experiencing, which allows the interrogator 106 to estimate the strain the fiber segment 116 experiences from the received optical power. The interrogator 106 digitizes the phase difference (“output signal”) whose magnitude and frequency vary directly with the magnitude and frequency of the dynamic strain the fiber segment 116 experiences.

The signal processing device 118 is communicatively coupled to the interrogator 106 to receive the output signal. The signal processing device 118 includes a processor 102 and a non-transitory computer-readable medium 104 that are communicatively coupled to each other. An input device 110 and a display 108 interact with the signal processing device 118. The computer-readable medium 104 has stored on it program code to cause the processor 102 (and consequently the signal processing device 118) to perform any suitable signal processing methods to the output signal. For example, if the fiber segment 116 is laid adjacent a region of interest that is simultaneously experiencing vibration at a rate under 20 Hz and acoustics at a rate over 20 Hz, the fiber segment 116 will experience similar strain and the output signal will comprise a superposition of signals representative of that vibration and those acoustics. The signal processing device 118 may apply to the output signal a low pass filter with a cut-off frequency of 20 Hz, to isolate the vibration portion of the output signal from the acoustics portion of the output signal. Analogously, to isolate the acoustics portion of the output signal from the vibration portion, the signal processing device 118 may apply a high-pass filter with a cut-off frequency of 20 Hz. The signal processing device 118 may also apply more complex signal processing methods to the output signal; example methods include those described in PCT application PCT/CA2012/000018 (publication number WO 2013/102252), the entirety of which is hereby incorporated by reference.

FIG. 1B depicts how the FBGs 114 reflect the light pulse, according to another embodiment in which the optical fiber 112 comprises a third FBG 114c. In FIG. 1B, the second FBG 114b is equidistant from each of the first and third FBGs 114a,c when the fiber 112 is not strained. The light pulse is propagating along the fiber 112 and encounters three different FBGs 114, with each of the FBGs 114 reflecting a portion 115 of the pulse back towards the interrogator 106. In embodiments comprising three or more FBGs 114, the portions of the sensing and reference pulses not reflected by the first and second FBGs 114a,b can reflect off the third FBG 114c and any subsequent FBGs 114, resulting in interferometry that can be used to detect strain along the fiber 112 occurring further from the interrogator 106 than the second FBG 114b. For example, in the embodiment of FIG. 1B, a portion of the sensing pulse not reflected by the first and second FBGs 114a,b can reflect off the third FBG 114c, and a portion of the reference pulse not reflected by the first FBG 114a can reflect off the second FBG 114b, and these reflected pulses can interfere with each other at the interrogator 106.

Any changes to the optical path length of the fiber segment 116 result in a corresponding phase difference between the reflected reference and sensing pulses at the interrogator 106. Since the two reflected pulses are received as one combined interference pulse, the phase difference between them is embedded in the combined signal. This phase information can be extracted using proper signal processing techniques, such as phase demodulation. The relationship between the optical path of the fiber segment 116 and that phase difference (θ) is as follows:

θ=2πnL/λ,

where n is the index of refraction of the optical fiber, L is the physical path length of the fiber segment 116, and λ is the wavelength of the optical pulses. A change in nL is caused by the fiber experiencing longitudinal strain induced by energy being transferred into the fiber. The source of this energy may be, for example, an object outside of the fiber experiencing dynamic strain, undergoing vibration, or emitting energy. As used herein, “dynamic strain” refers to strain that changes over time. Dynamic strain that has a frequency of between about 5 Hz and about 20 Hz is referred to by persons skilled in the art as “vibration”, dynamic strain that has a frequency of greater than about 20 Hz is referred to by persons skilled in the art as “acoustics”, and dynamic strain that changes at a rate of <1 Hz, such as at 500 μHz, is referred to as “sub-Hz strain”.

Another way of determining ΔnL is by using what is broadly referred to as distributed acoustic sensing (“DAS”). DAS involves laying the fiber 112 through or near a region of interest and then sending a coherent laser pulse along the fiber 112. As shown in FIG. 1C, the laser pulse interacts with impurities 113 in the fiber 112, which results in scattered laser light 117 because of Rayleigh scattering. Vibration or acoustics emanating from the region of interest results in a certain length of the fiber becoming strained, and the optical path change along that length varies directly with the magnitude of that strain. Some of the scattered laser light 117 is back-scattered along the fiber 112 and is directed towards the optical receiver 103, and depending on the amount of time required for the scattered light 117 to reach the receiver and the phase of the scattered light 117 as determined at the receiver, the location and magnitude of the vibration or acoustics can be estimated with respect to time. DAS relies on interferometry using the reflected light to estimate the strain the fiber experiences. The amount of light that is reflected is relatively low because it is a subset of the scattered light 117. Consequently, and as evidenced by comparing FIGS. 1B and 1C, Rayleigh scattering transmits less light back towards the optical receiver 103 than using the FBGs 114.

DAS accordingly uses Rayleigh scattering to estimate the magnitude, with respect to time, of the strain experienced by the fiber during an interrogation time window, which is a proxy for the magnitude of the vibration or acoustics emanating from the region of interest. In contrast, the embodiments described herein measure dynamic strain using interferometry resulting from laser light reflected by FBGs 114 that are added to the fiber 112 and that are designed to reflect significantly more of the light than is reflected as a result of Rayleigh scattering. This contrasts with an alternative use of FBGs 114 in which the center wavelengths of the FBGs 114 are monitored to detect any changes that may result to it in response to strain. In the depicted embodiments, groups of the FBGs 114 are located along the fiber 112. A typical FBG can have a reflectivity rating of between 0.1% and 5%. The use of FBG-based interferometry to measure dynamic strain offers several advantages over DAS, in terms of optical performance.

In various embodiments herein in which the event detection system comprises a pipeline leak detection system, either FBG-based sensors or DAS-based sensors as described above may be used to generate a data stream of sensor readings. Simulated events are blended into that data stream for processing by the event detection system, as described below.

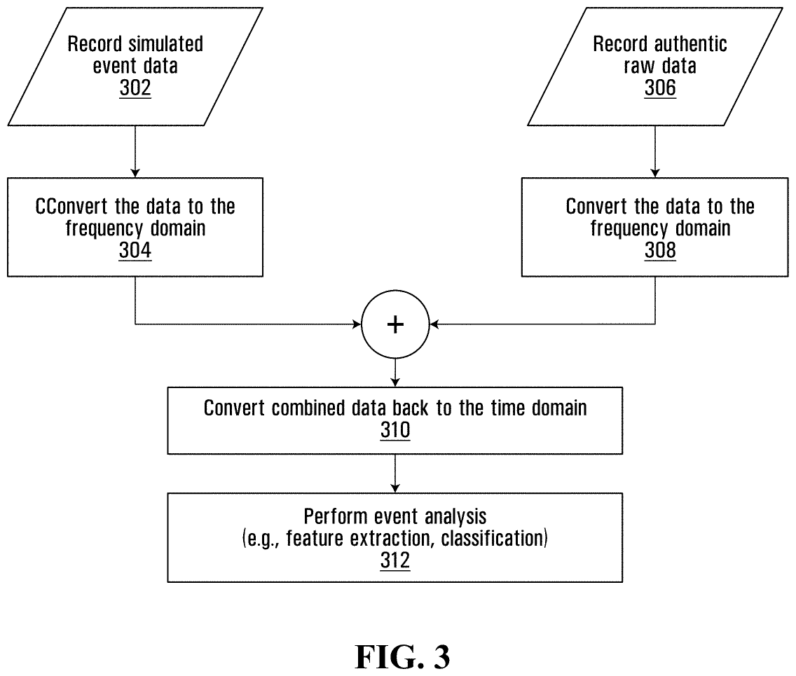

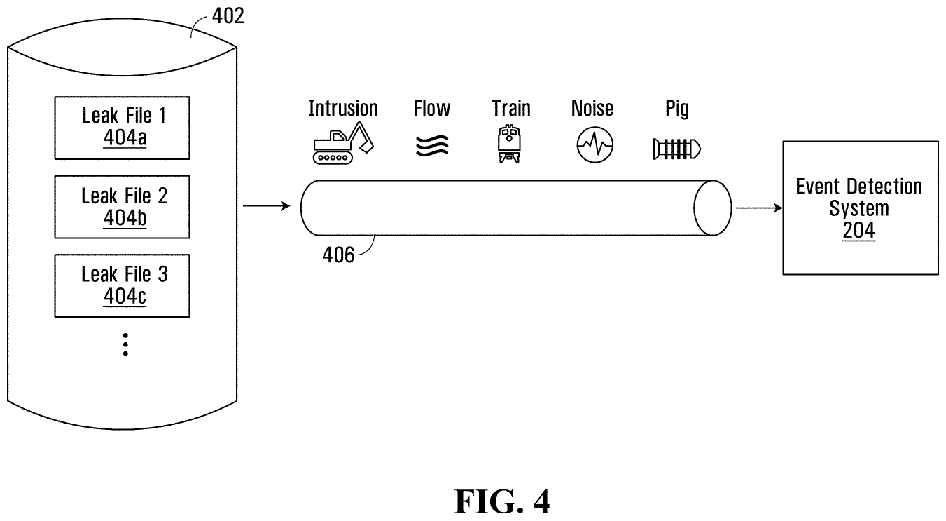

More particularly and with reference to FIGS. 2A and 2B, there are respectively depicted an event detection system 204 operating in accordance with the prior art (FIG. 2A) and an event detection system 204 operating in accordance with an example embodiment (FIG. 2B). The event detection system 204 may, for example, collectively comprise the signal processing device 118, interrogator 106, display 108, and input device 110.

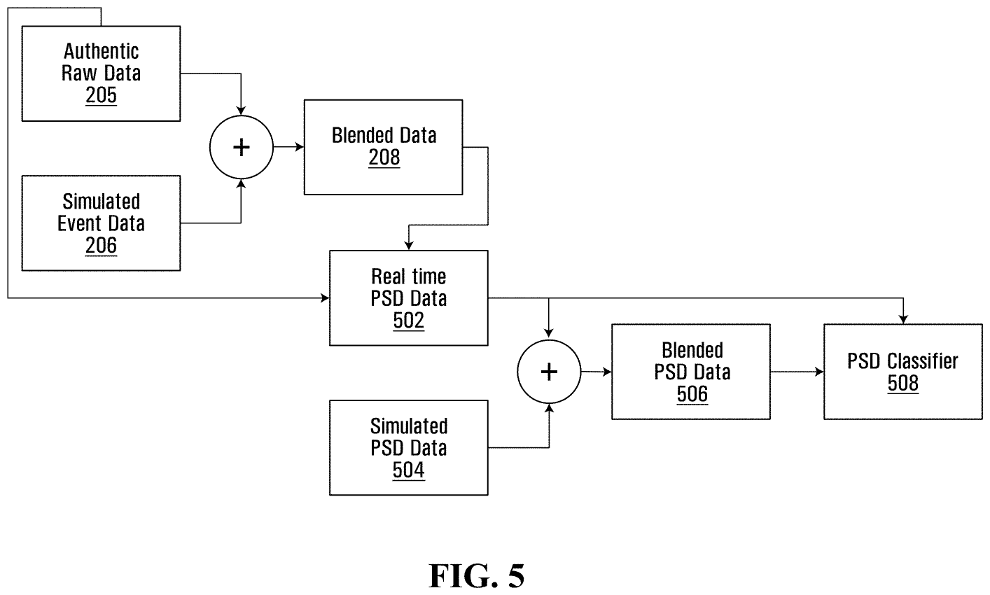

In FIG. 2A, a data stream comprising authentic events (“authentic event data 202”) is input to the event detection system 204. In contrast, in FIG. 2B authentic raw data 205 is combined with a data stream comprising simulated events (“simulated event data 206”) as described in more detail below in FIG. 3. The result of the combination is blended data 208, which is fed into the event detection system 204 for processing. The authentic event data 202 may be obtained in real-time (e.g., real-time acoustic data collected by distributed fiber optic sensors monitoring a pipeline, as described above in respect of FIGS. 1A and 1B) or historical data (e.g., data recorded from a camera system). The portion of the authentic raw data 205 that is combined with the simulated event data 206 in at least some example embodiments lacks an authentic event so that when combined with the simulated event data 206, the event detection system 204 is tasked with only identifying the simulated event from the simulated event data 206 as opposed to the simulated event and an authentic event. In some other example embodiments, the portion of the authentic raw data 205 that is combined with the simulated event data 206 also comprises an authentic event, in which case the blended data 208 presented to the event detection system 204 for processing comprises the authentic event and the simulated event. The event detection system 204 then faces the technical challenge of identifying and distinguishing between two events.

Referring now to FIG. 3, there is depicted a method for simulating an event, according to an example embodiment. In the example of FIG. 3, authentic raw data 205 is recorded at block 306. In this example, the authentic raw data 205 is acoustic data streaming from sensors such as the FBG-based or DAS-based sensors discussed above in respect of FIGS. 1A-1C when used to monitor a pipeline for leaks. The authentic raw data 205 is converted to the frequency domain at block 308 by, for example, determining the Fourier transform of the authentic raw data 205. The authentic raw data 205 may differ from the authentic event data 202 in that the authentic event data 202 comprises an authentic event whereas the authentic raw data 205 of block 306 need not (e.g., it may comprise only ambient noise).

Analogously, simulated data 206 is recorded at block 302. In this example embodiment, the simulated data 206 is recorded from a field-simulated pipeline leak; in at least some other embodiments as discussed below, the simulated data may be generated using an artificial neural network such as a generative adversarial network. As another example, the simulated data 206 may be based on an actual authentic event, such as a pipeline leak, and used as the basis for one or more simulated events for the same event detection system 204 used to obtain the event or for other event detection systems 204. Analogous to block 308, the simulated data 206 is converted into the frequency domain at block 304 by, for example, determining its Fourier transform.

The frequency domain representations of the simulated data 206 and authentic raw data 205 are added together to result in the blended data 208 (not depicted in FIG. 3). In this example, the blended data 208 comprises ambient pipeline acoustics from the authentic raw data 205 and the simulated leak from the simulated data 206. Adding the authentic raw data 205 and the simulated data 206 in the frequency domain has the advantage in at least some embodiments of eliminating phase lag and misaligned timing of events (i.e., the fact that an authentic event present in the authentic raw data 205 may not be synchronized with the simulated event). While FIG. 3 sums the frequency domain representations of the simulated data 206 and authentic raw data 205 together to result in the blended data 208, in other embodiments the simulated data 206 and authentic raw data 205 can be combined in other ways. For example, both the simulated data 206 and authentic raw data 205 may be represented in the time domain and a convolution may be performed of the authentic raw data's 205 time domain representation with the simulated data's 206 time domain representation. Alternatively, the blended data 208 may be generated by summing time domains representations of the authentic raw data 205 and simulated data 206 together.

At block 310 the blended data 208 is converted from the frequency domain to the time domain. This may be done by determining the inverse Fourier transform of the blended data 208. The resulting data is a time domain representation of the blended data 208 comprising the ambient pipeline acoustics and the simulated leak.

The data may then be processed using the event detection system 204 at block 312. The event detection system 204 may perform event analysis such as feature extraction and classification by applying, for example, machine learning.

In FIG. 3, the simulated data 206 and authentic raw data 205 recorded at blocks 302 and 306 is recorded in the time domain. Consequently, conversion of that data into the frequency domain at blocks 304 and 308 and conversion of the summed frequency domain data back into the time domain and block 310 is performed. However, in at least some other embodiments, for example as discussed further below in respect of data expressed as power spectral densities, data may obtained and processed in the frequency domain, thereby obviating any need for conversions between the time and frequency domains.

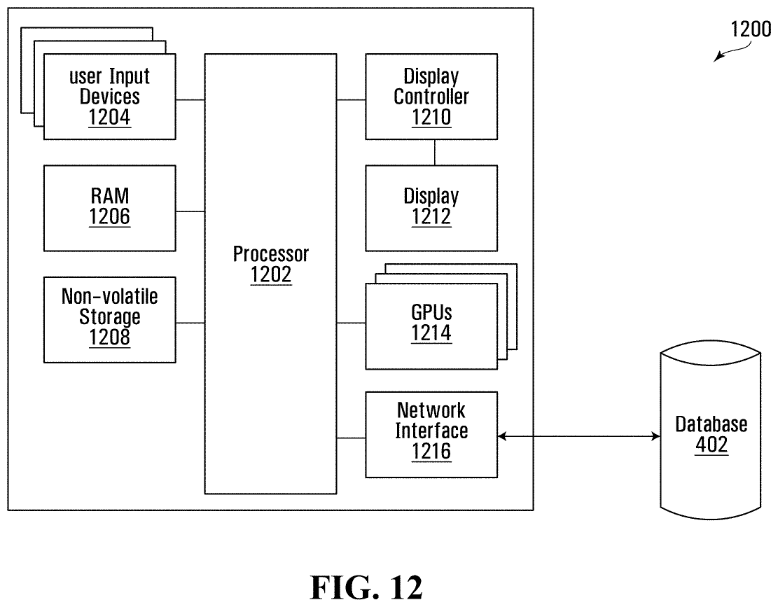

The method of FIG. 3 may be implemented at least in part by one or more computer systems, such as the computer system 1200 depicted in FIG. 12. FIG. 12 shows a block diagram of an example computer system 1200 comprising a processor 1202 that controls the system's 1200 overall operation. The processor 1202 is communicatively coupled to and controls subsystems comprising user input devices 1204, which may comprise any one or more user input devices such as a keyboard, mouse, touch screen, and microphone; random access memory (“RAM”) 1206, which stores computer program code that is executed at runtime by the processor 1202; non-volatile storage 1208 (e.g., a solid state drive or magnetic spinning drive), which stores the computer program code loaded into the RAM 1204 for execution at runtime and other data; a display controller 1210, which may be communicatively coupled to and control a display 1212; graphical processing units (“GPUs”) 1214, used for parallelized processing as is not uncommon in vision processing tasks and related artificial intelligence operations; and a network interface 1216, which facilitates network communications with a network and other devices that may be connected thereto.

Blocks 302 and 306 of FIG. 3 may be implemented by obtaining data using physical sensors and recording that data in the computer system's 1200 non-volatile storage 1208. The processor 1202 may then perform blocks 304, 308, and 310, and output the data via the network interface 1216 to the event detection system 204 for the processing of block 312.

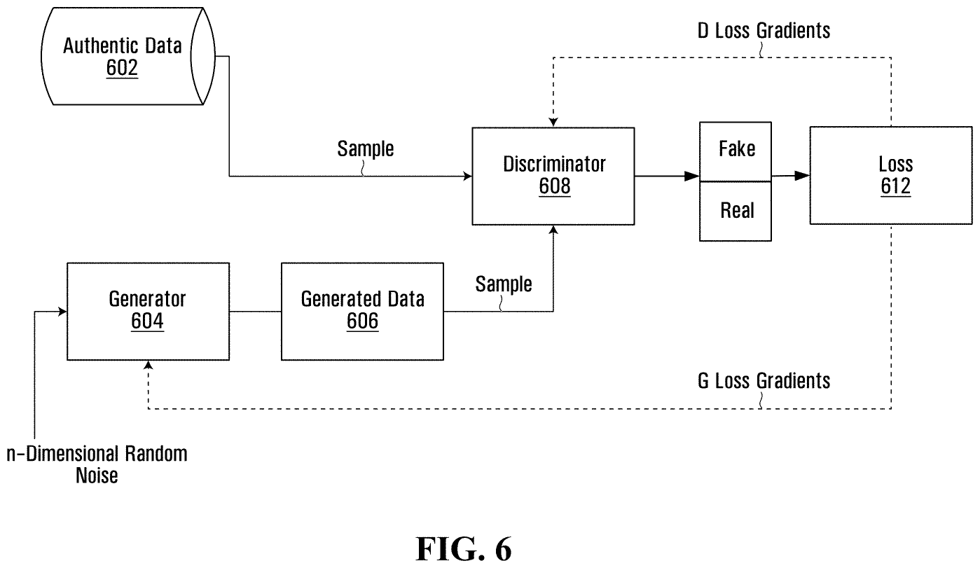

The computer system 1200 also comprises a database 402 that is communicatively coupled to the processor 1202 via the network interface 1216. As shown in FIG. 4, the database 402 may be used to store multiple leak files such as first through third leak files 404a-c, with each of the leak files 404a-c storing simulated data 206 corresponding to a simulated leak. The different leak files 404a-c may simulate different kinds of leaks under different conditions (e.g., they may differ in any one or more of loudness and frequency).

While various types of leak files 404a-c are shown in FIG. 4, in at least some other embodiments the database 402 may additionally or alternatively store files of various types of simulated events for various types of event detection systems 204, respectively, thereby permitting the same database 402 to be used for different systems 204.

The database 402 in FIG. 4 is combined with authentic raw data 205 generated as a result of monitoring a pipeline 406 using an FBG-based or DAS-based system such as those described above in respect of FIGS. 1A-1C. The blending of the simulated data 206 and authentic raw data 205 may be performed as described above in FIG. 3, for example. As shown in FIG. 4, the authentic raw data 205 may comprise acoustic interference that results from one or more of a pipeline intrusion such as by a piece of heavy equipment; fluid flow within the pipeline; a train or other vehicle moving in the vicinity of the pipeline 406; ambient noise; and a pig moving through the pipeline 406. The blended data 208 resulting from blending one or more of the leak files 404a-c with the authentic raw data 205 is sent to the event detection system 204 for further processing.

FIG. 5 depicts another example embodiment of a system for simulating an event. The system of FIG. 5 may be used, for example, to detect acoustic events (events with a frequency of over about 20 Hz) and strain events more generally, which may be of any frequency as described above in respect of FIGS. 1A-1C. More particularly, the system of FIG. 5 comprises the authentic raw data 205, simulated event data 206, and the blended data 208 as discussed above in respect of FIG. 2B. FIG. 5 further depicts real time power spectral density (“PSD”) data 502 and simulated PSD data 504 that are summed together to create blended PSD data 506. The blended PSD data 506 is sent to a PSD classifier 508 for classification in a manner analogous to that described in respect of time-domain data for block 312 of FIG. 3.

More particularly, the real time PSD data 502 in FIG. 5 represents two types of PSD data: one, PSD data that results from converting the authentic raw data 205 into PSD data, with this PSD data being fed into the PSD classifier 508; and two, PSD data that results from converting the blended data 208 into PSD data, which is combined with the simulated PSD data to generated the blended PSD data 506. This blended PSD data 506 is also then fed to the PSD classifier. The PSD of each incoming acoustic frame is determined and turned into an image (each a “PSD image”). The PSD classifier 508 comprises an artificial neural network, such as a convolutional neural network, that has been trained to distinguish between PSD images of leak events and non-leak events by virtue of being trained with PSD images corresponding to acoustic data recorded during field leak simulations. The neural network consequently is able to process various features in the PSD images to detect the leak events.

The architecture of FIG. 5 provides multiple ways to blend data representing a simulated leak with real time acoustic data. For example, the authentic raw data 205 and simulated event data 206 may be combined to form the blended data 208 in the time domain, which is then converted into real time PSD data 502 that is sent to the PSD classifier 508. In this way, the simulated event data 206 is the source of the simulated event.

Alternatively, the simulated event may be generated in PSD form as opposed to converted to PSD form. In this case, the simulated event is represented in the simulated PSD data 504, which is combined with the real time PSD data 502 that is the PSD representation of the authentic raw data 205. This real time PSD data 502 and the simulated PSD data 504 are combined together to result in the blended PSD data 506, which is fed to the PSD classifier 508. A reference to combining two PSD images together herein refers to summing the frequency domain data that is used to generate the PSD images analogous to how frequency domain data is combined in respect of FIG. 3 above, and then generating a resulting PSD image from the combined frequency domain data. Generating a PSD image of the type referred to in at least some embodiments herein from frequency domain data comprises generating a spectrogram, which plots signal magnitude vs. time vs. signal frequency. While magnitude, time, and frequency are three variables, the PSD image is rendered in two-dimensions by virtue of using various shades of grey or color to represent signal magnitude. Accordingly, in those embodiments the PSD image comprises a 2D image with time along one axis and frequency along another, with various shades of grey or color representing signal magnitude.

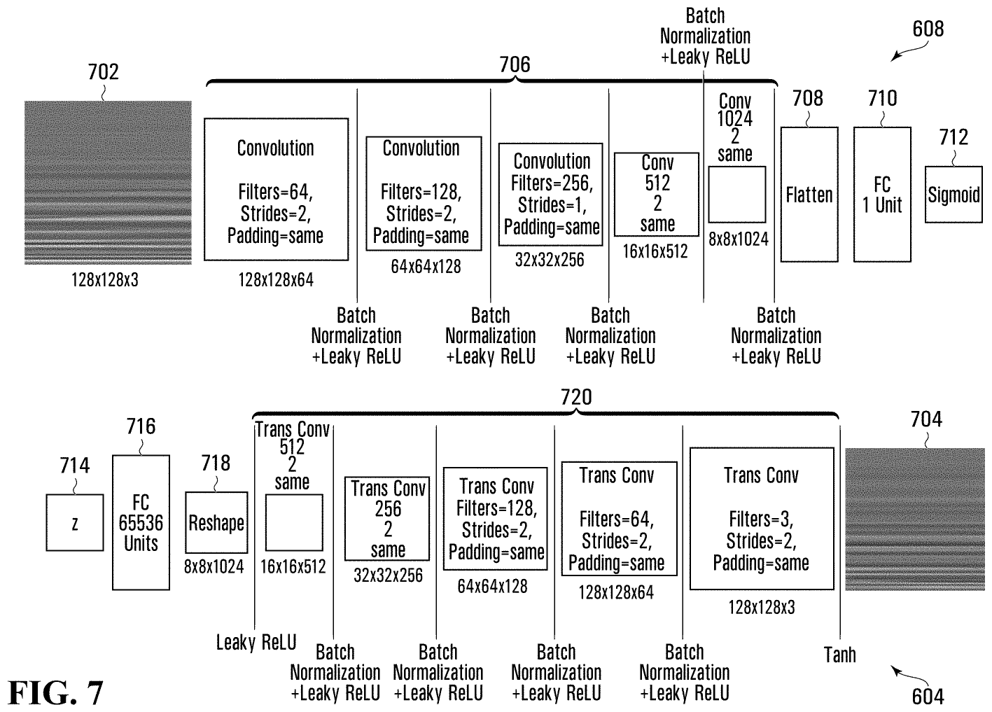

Images depicting simulated PSD events (“simulated PSD images”) may be generated using a suitable generative adversarial network (“GAN”), such as that depicted in FIG. 6. A GAN generates simulated PSD images based on an original PSD image. More particularly, the GAN of FIG. 6 comprises two deep neural networks: a generator network labeled as generator 604 in FIG. 6, and a discriminator network labeled as discriminator 608 in FIG. 6. The generator 604 takes n-dimensional random noise as input to generate simulated data labeled in FIG. 6 as generated data 606 that is similar to an image depicting an authentic PSD event (each an “authentic PSD image”). Authentic PSD images are stored in a database 602, and authentic PSD images and simulated PSD images are input to the discriminator 608. The discriminator 608 attempts to differentiate between the authentic and simulated images and outputs a loss 612, which reflects the distance between the distribution of the data generated by the GAN and the distribution of the authentic data in the database 602, that is fed back to the discriminator 608 and generator 604, with the generator 604 attempting to minimize the loss 612 while the discriminator 608 tries to maximize it. A suitable GAN is described, for example, in Shorten, C., Khoshgoftaar, T. M., A survey on image data augmentation for deep learning, J. Big Data 2019, 6, 60, the entirety of which is hereby incorporated by reference.

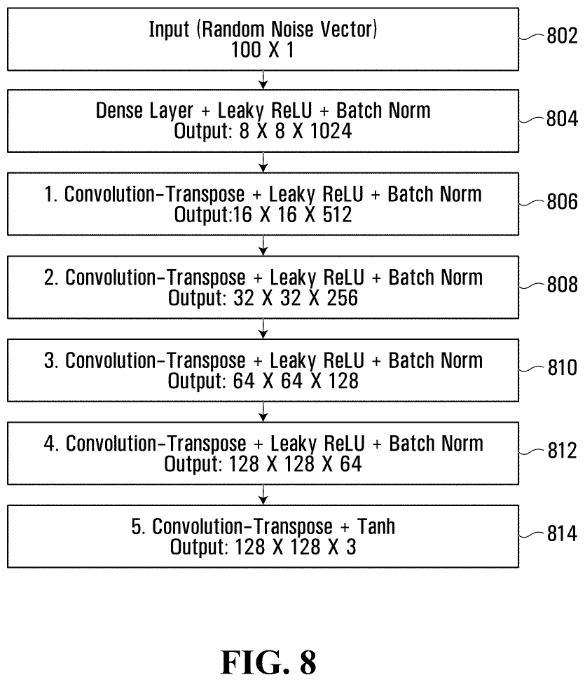

FIG. 7 depicts a block diagram depicting the various layers and parameters of an example generator 604 and an example discriminator 608 that comprise part of an example GAN known as a deep convolutional generative adversarial network (“DCGAN”). A DCGAN comprises one or more convolutional layers 706 and convolutional transpose layers 720 (interchangeably referred to as “transpose convolutional” or “deconvolutional” layers), as shown in FIG. 7. More particularly, a noise vector 714 is input to the generator 604, which outputs a simulated PSD image 704 of a simulated leak event. The noise vector 714 is sequentially processed by a fully connected layer 716, a reshape layer 718, and the convolutional transpose layers 720 prior to resulting in the simulated PSD image 704. An authentic PSD image 702 from the database 602 representing an authentic leak event is input to the discriminator 608. A sigmoid function 712 at the output of the discriminator 608 determines whether the image is authentic or simulated. More particularly, the authentic PSD image 702 is sequentially processed by the convolutional layers 706, a flatten layer 708, and a fully connected layer 710 before being input to the sigmoid function 712. In FIG. 7, the discriminator 608 applies batch normalization and a Leaky Rectified Linear Unit (“Leaky ReLU”) activation function to the output of each of the convolutional layers 706. The generator 604 also uses batch normalization and Leaky ReLU to the output of each of the convolutional transpose 720 layers except for the last convolutional transpose 720 layer, which uses a Tan h activation function.

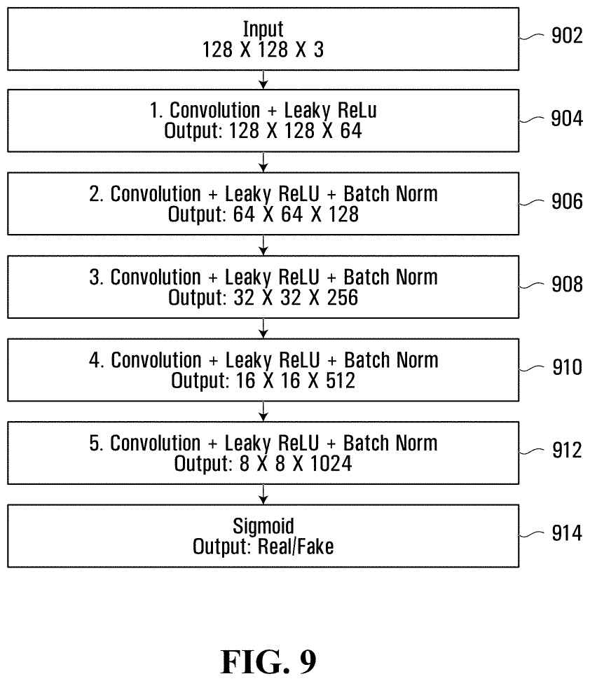

Blocks 802-814 of FIG. 8 depict the layers that comprise the example embodiment of the generator 604 of FIG. 7. In the generator 604 of FIG. 8, a 100×1 random noise vector is used as input (block 802). The noise vector is passed to the dense layer and is reshaped to 8×8×1024 (block 804) using the reshape layer 718. To create an image size of 128×128×3, the output of the dense layer is followed by a series of convolution-transpose layers 720 to up-sample the image (blocks 806, 808, 810, and 812). Leaky ReLU activation is used for all layers except the output, which uses Tan h activation. This helps the generator 604 achieve saturation quickly. Batch normalization is used for every layer except for the output layer. This helps to normalize the input to have zero mean to sustain the training process. In FIG. 8, five convolutional transpose 720 layers are used to obtain an image size of 128×128×3 at the output of block 814.

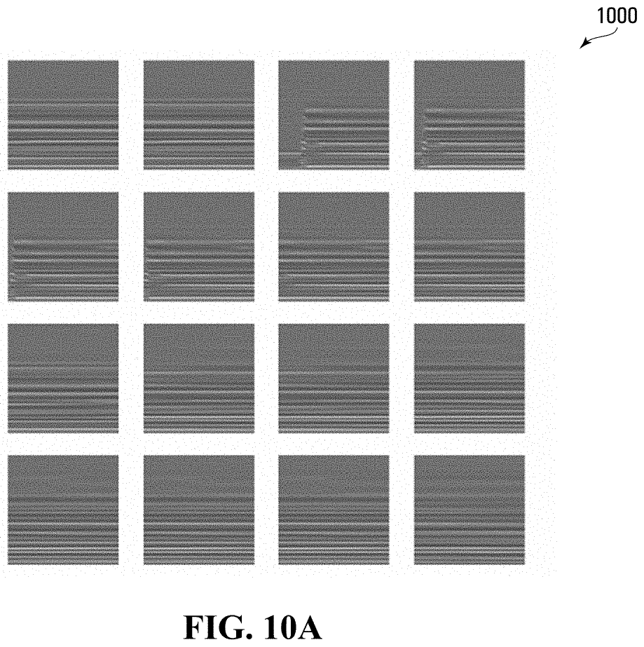

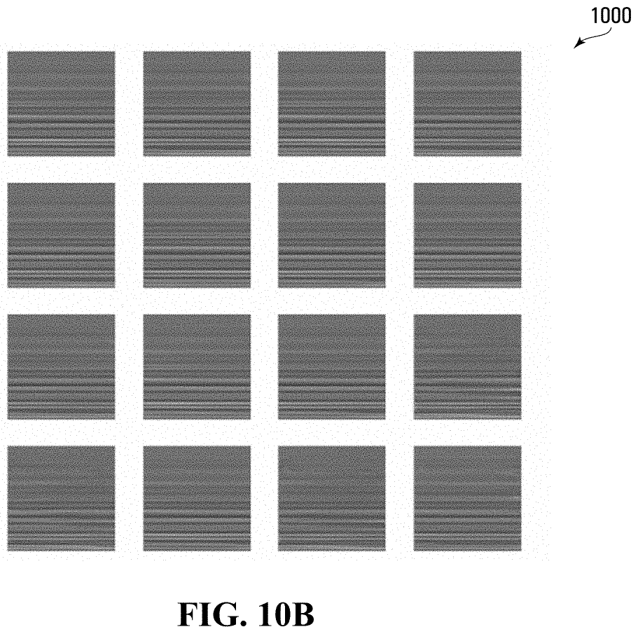

Blocks 912-914 of FIG. 9 depict the layers that comprise the example embodiment of the discriminator 608 of FIG. 7. The goal of the discriminator 608 of FIG. 9 is to classify whether the PSD images input to it are authentic or simulated. The discriminator 608 takes images of size 128×128×3 as input (block 902), selected as either authentic PSD images from the database 602 and the simulated PSD images obtained from the generator 604. In FIG. 10, the input PSD image undergoes a series of convolutions (blocks 904, 906, 908, 910, and 912), followed by a sigmoid activation function (block 914) to determine whether the PSD image is authentic or simulated. A Leaky ReLU activation function follows each convolution layer, and Batch Norm is applied to all layers except the input layers.

Generally speaking, when applying a DCGAN in at least some example embodiments Batch Norm is used in both the generator 604 and discriminator 608; fully connected hidden layers may be removed for a deeper architecture; Leaky ReLU activation may be used in the generator 604 for all layers except the output, which uses Tan h; and Leaky ReLU activation may be used in all layers of the discriminator 608.

When training a GAN in at least some example embodiments, the generator 604 may be trained to maximize the final classification error between authentic and simulated PSD images, while the discriminator 608 is trained to reduce that error. The generator 604 reaches equilibrium when the generated data 606 produces samples that follow the probability distribution of the authentic PSD images stored in the database 602 and used to train the discriminator 608. The discriminator 608 is trained directly on the authentic PSD images in the database 602 and on simulated PSD images generated by the generator 604, while the generator 604 is trained via the discriminator 608. Convergence of the generator 604 and discriminator 608 signals the end of training. When the discriminator 608 is being trained, the loss 612 returned to the generator 604 is ignored and only the discriminator 608 loss is used; this penalizes the discriminator 608 for misclassifying authentic leaks as simulated or simulated leaks as authentic (the generator's 604 weights are not updated during discriminator 608 training). When the generator 604 is being trained, the loss 612 returned to the generator 604 is used, which penalizes the generator 604 for failing to fool the discriminator 608 using the simulated PSD images it generates.

FIGS. 10A and 10B depict the authentic PSD images 1000 used to train an example GAN and the simulated PSD images resulting from the trained DCGAN, which corresponds to the GAN depicted in FIGS. 7-9. The DCGAN was trained for 500 epochs. The DCGAN was able to generate simulated PSD images depicting simulated leak events after 60 epochs; the remaining epochs were used to improve image quality and features. The discriminator 608 determines that the simulated PSD image is 97.7% accurate with respect to the authentic PSD image used to generate the simulated PSD image.

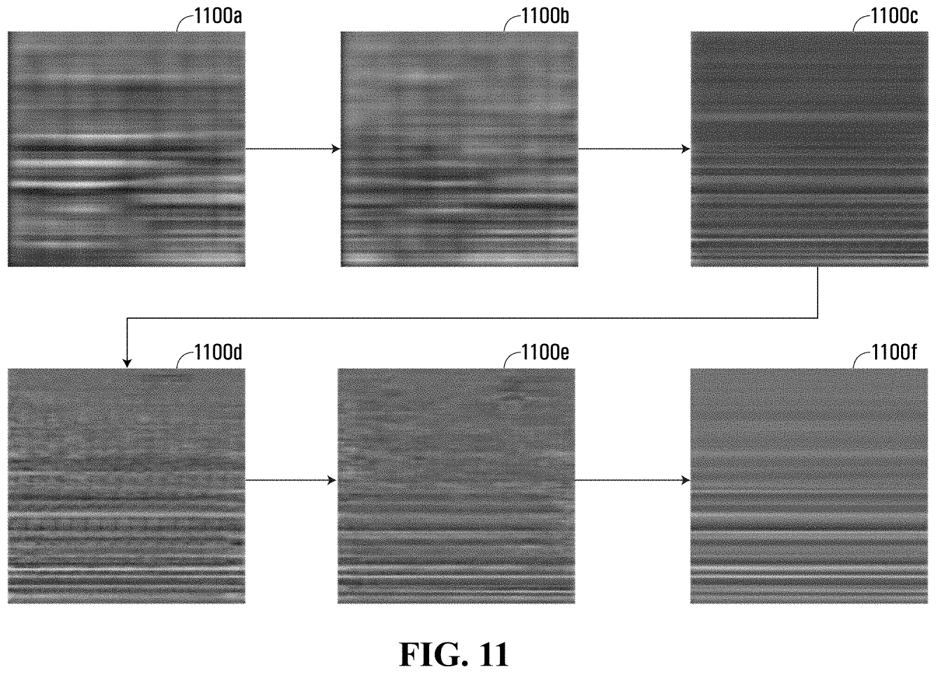

FIG. 11 shows example first through sixth simulated PSD images 1100a-f output by an example embodiment of the DCGAN trained using the images 1000 of FIGS. 10A and 10B, with the amount the DCGAN was trained increasing from the first to the sixth images 1100a-f. Ultimately, the sixth image 1100f is 97.7% accurate relative to the authentic PSD images used to train the DCGAN (i.e., 97.7% of the features in the last image 1100f are found somewhere in the authentic PSD images used to train the DCGAN, with 2.3% of the features in the last image 1200f being found nowhere in the authentic PSD images used for training). The discriminator 608 is trained to categorize authentic and simulated PSD images correctly; this is achieved by maximizing the log of predicted probability of real images and the log of the inverted probability of simulated images, averaged over each mini-batch of examples. This can be understood as the loss function seeking probabilities close to 1.0 for authentic images and probabilities close to 0.0 for simulated images.

The various embodiments of the GAN depicted in FIGS. 6-9 may also be implemented using the computer system 1200 of FIG. 12. More particularly, computer program code implementing the GAN may be stored in the non-volatile storage 1208 and subsequently executed by the processor 1202. The processor 1202 may in particular implement the GAN using the GPUs 1214 to increase machine learning performance. Authentic data stored in the database 602 of FIG. 6 may be stored in the database 402 of FIG. 12 and consequently accessed by the GAN.

The processor 1202 may comprise any suitable processing unit such as a processor, microprocessor, artificial intelligence accelerator, or programmable logic controller, or a microcontroller (which comprises both a processing unit and a non-transitory computer readable medium), or system-on-a-chip (SoC). Examples of computer readable media that are non-transitory include disc-based media such as CD-ROMs and DVDs, magnetic media such as hard drives and other forms of magnetic disk storage, semiconductor based media such as flash media, random access memory (including DRAM and SRAM), and read only memory. As an alternative to an implementation that relies on processor-executed computer program code, a hardware-based implementation may be used. For example, an application-specific integrated circuit (ASIC), field programmable gate array (FPGA), or other suitable type of hardware implementation may be used as an alternative to or to supplement an implementation that relies primarily on a processor executing computer program code stored on a computer medium.

The embodiments have been described above with reference to flow, sequence, and block diagrams of methods, apparatuses, systems, and computer program products. In this regard, the depicted flow, sequence, and block diagrams illustrate the architecture, functionality, and operation of implementations of various embodiments. For instance, each block of the flow and block diagrams and operation in the sequence diagrams may represent a module, segment, or portion of code, which comprises one or more executable instructions for implementing the specified action(s). In some alternative embodiments, the action(s) noted in that block or operation may occur out of the order noted in those figures. For example, two blocks or operations shown in succession may, in some embodiments, be executed substantially concurrently, or the blocks or operations may sometimes be executed in the reverse order, depending upon the functionality involved. Some specific examples of the foregoing have been noted above but those noted examples are not necessarily the only examples. Each block of the flow and block diagrams and operation of the sequence diagrams, and combinations of those blocks and operations, may be implemented by special purpose hardware-based systems that perform the specified functions or acts, or combinations of special purpose hardware and computer instructions.

The terminology used herein is for the purpose of describing particular embodiments only and is not intended to be limiting. Accordingly, as used herein, the singular forms “a”, “an”, and “the” are intended to include the plural forms as well, unless the context clearly indicates otherwise (e.g., a reference in the claims to “a challenge” or “the challenge” does not exclude embodiments in which multiple challenges are used). It will be further understood that the terms “comprises” and “comprising”, when used in this specification, specify the presence of one or more stated features, integers, steps, operations, elements, and components, but do not preclude the presence or addition of one or more other features, integers, steps, operations, elements, components, and groups. Directional terms such as “top”, “bottom”, “upwards”, “downwards”, “vertically”, and “laterally” are used in the following description for the purpose of providing relative reference only, and are not intended to suggest any limitations on how any article is to be positioned during use, or to be mounted in an assembly or relative to an environment. Additionally, the term “connect” and variants of it such as “connected”, “connects”, and “connecting” as used in this description are intended to include indirect and direct connections unless otherwise indicated. For example, if a first device is connected to a second device, that coupling may be through a direct connection or through an indirect connection via other devices and connections. Similarly, if the first device is communicatively connected to the second device, communication may be through a direct connection or through an indirect connection via other devices and connections. The term “and/or” as used herein in conjunction with a list means any one or more items from that list. For example, “A, B, and/or C” means “any one or more of A, B, and C”.

It is contemplated that any part of any aspect or embodiment discussed in this specification can be implemented or combined with any part of any other aspect or embodiment discussed in this specification.

The scope of the claims should not be limited by the embodiments set forth in the above examples, but should be given the broadest interpretation consistent with the description as a whole.

It should be recognized that features and aspects of the various examples provided above can be combined into further examples that also fall within the scope of the present disclosure. In addition, the figures are not to scale and may have size and shape exaggerated for illustrative purposes.

1. A method comprising:
(a) obtaining simulated event data comprising a simulated event and authentic raw data; and
(b) combining the simulated event data and the authentic raw data to form blended data that comprises the simulated event.

2. The method of claim 1, further comprising subsequently processing the blended data and identifying the simulated event therein.

3. The method of claim 1, wherein combining the simulated event data and the raw data to form blended data comprises:
(a) respectively converting the simulated event data and the authentic raw data into frequency domain representations thereof;
(b) summing the frequency domain representations of the simulated event data and the authentic raw data together to form a frequency domain representation of the blended data; and
(c) converting the frequency domain representation of the blended data into a time domain representation of the blended data.

4. The method of claim 1, wherein the blended data is expressed as a power spectral density.

5. The method of claim 4, wherein the simulated event data is expressed as a power spectral density when combined with the authentic raw data.

6. The method of claim 1, wherein the simulated event data comprises recorded authentic events.

7. The method of claim 5, further comprising generating the simulated event data using a generative adversarial network, wherein some of the authentic raw data is input to the generative adversarial network to permit generation of the simulated event data.

8. The method of claim 6, wherein the generative adversarial network comprises a generator and a discriminator, wherein all layers except an output layer of the discriminator use leaky rectified linear unit activation, the output layer of the discriminator uses tan h activation, and all layers of the generator use leaky rectified linear unit activation.

9. The method of claim 1, wherein the authentic raw data comprises acoustic data.

10. The method of claim 8, wherein obtaining the authentic raw data comprises performing optical fiber interferometry using fiber Bragg gratings.

11. The method of claim 8, wherein obtaining the authentic raw data comprises performing distributed acoustic sensing.

12. The method of claim 1, wherein the authentic raw data is obtained and combined with the simulated event data in real-time.

13. The method of claim 1, wherein the authentic raw data is obtained by recording acoustics proximate a pipeline, and wherein the simulated event comprises a pipeline leak.

14. A system comprising:
(a) a processor;
(b) a database that is communicatively coupled to the processor and that has simulated event data stored thereon;
(c) a memory that is communicatively coupled to the processor and that has stored thereon computer program code that is executable by the processor and that, when executed by the processor, causes the processor to perform a method comprising:
(i) obtaining, from the database, the simulated event data comprising a simulated event and authentic raw data; and
(ii) combining the simulated event data and the authentic raw data to form blended data that comprises the simulated event.

15. A non-transitory computer readable medium having stored thereon computer program code that is executable by a processor and that, when executed by the processor, causes the processor to perform a method comprising:
(a) obtaining simulated event data comprising a simulated event and authentic raw data; and
(b) combining the simulated event data and the authentic raw data to form blended data that comprises the simulated event.
